(19) United States
(12) Patent Application Publication
(10) Pub. No.: US 2025/0098286 A1
(43) Pub. Date: Mar. 20, 2025

(54) Reduction of Edge Transistor Leakage on N-Type EDMOS and LDMOS Devices

(71) Applicant: Murata Manufacturing Co., Ltd., Kyoto (JP)

(72) Inventors: Jagar Singh, Clifton Park, NY (US); Mari Saji, San Diego, CA (US); Akira Fujihara, San Diego, CA (US)

(21) Appl. No.: 18/468,556

(22) Filed: Sep. 15, 2023

(51) Int. Cl. H01L 27/06; H01L 29/06; H01L 29/10; H01L 29/78

(52) U.S. Cl. CPC H10D 84/40; H10D 30/603; H10D 62/127; H10D 62/393

(57) ABSTRACT

MOSFET-based IC architectures, including SOI NEDMOS ICs and bulk semiconductor LDMOS ICs, that mitigate or eliminate the problems of edge transistors. One IC embodiment includes end-cap body contact regions angle-implanted to have a first characteristic (e.g., P+), a drift region, and a gate structure partially overlying the end-cap body contact regions and the drift region and including a conductive layer having a third characteristic (e.g., N+) and a first side angle-implanted to have the first characteristic. Steps for fabricating such an IC include implanting a dopant at an angle in the range of about 5° to about 60° within the end-cap body contact regions and within the first side of the conductive layer in a region of the gate structure overlying the end-cap body contact regions, wherein the angle-implanted dopant results in the first characteristic for the end-cap body contact regions and the first side of the conductive layer.

### BACKGROUND

### (1) Technical Field

This invention relates to electronic integrated circuits, and more particularly to electronic integrated circuits having metal-oxide-semiconductor field-effect transistors (MOSFETs).

### (2) Background

Virtually all modern electronic products-including laptop computers, mobile telephones, and electric cars-utilize MOSFET-based integrated circuits (ICs). MOSFET-based ICs may be fabricated on bulk silicon or may be fabricated using a semiconductor-on-insulator (SOI) process, such as silicon-on-insulator, germanium-on-insulator, or silicon/germanium-on-insulator (e.g., a SiGe alloy or a layer of Ge on a layer of Si formed on an insulator).

A number of architectural variations exist for MOSFETs. For example, N− type Extended Drain MOS (NEDMOS) FETs fabricated using SOI processes and Laterally-Diffused MOS (LDMOS) FETs fabricated using bulk silicon are common transistor devices capable of handling relatively high drain voltages. For example, FIG. 1A is a stylized cross-sectional view of a typical prior art SOI IC structure for a single NEDMOS FET 100. The SOI structure includes a substrate 102, a buried-oxide (BOX) insulator layer 104, and an active layer 106 (note that the dimensions for the elements of the SOI IC structure are not to scale; some dimensions have been exaggerated for clarity or emphasis). The substrate 102 is typically a semiconductor material such as silicon. The BOX layer 104 is a dielectric, and is often SiO₂ formed as a “top” surface of the silicon substrate 102.

The active layer 106 may include some combination of implants and/or layers that include dopants, dielectrics, polysilicon, conductors, passivation, and other materials to form active and/or passive electronic components and/or mechanical structures. For example, FIG. 1A shows an NEDMOS FET 100 that includes an N+ source S, a P+ body region B, a gate structure G, an N− drift region, and an N+ drain D. The designation “N− means a lesser concentration of N-type dopant (e.g., arsenic or phosphorous) than the designation “N+”. A conductive source contact 112, a conductive gate contact 114, and a conductive drain contact 116, which may be self-aligned silicides (also known as “salicides”), are respectively formed in contact with the source S, the gate structure G, and the drain D. Stylized electrical terminals S, G, and D are shown coupled to the corresponding source contact 112, gate contact 114, and contact 116.

The illustrated gate structure G includes a conductive layer 108, such as N+ doped polysilicon, atop an insulating gate oxide (GOX) layer 110. In the illustrated example, the gate structure G is surrounded by insulating spacers 118. Part of the gate structure G and the drift region are coated with a dielectric 120, such as SiO₂, Si₃N₄, etc., which in turn is overlaid with a salicide block (SAB) layer 122, such as silicon nitride (SiN). In some embodiments, a lightly-doped drain (LDD) region 124 may be formed underneath the spacer 118 adjacent the source S. In some embodiments, a doped halo region 126 may be formed between at least portions of the source S and body B.

The BOX layer 104 and the active layer 106 (which may include multiple FETs) may be collectively referred to as a “device region” or “substructure” 130 for convenience (noting that other structures or regions may intrude into the substructure 130 in particular IC designs). A superstructure 132 of various elements, regions, and structures may be fabricated on or above the substructure 130 in order to implement particular functionality. The superstructure 132 may include, for example, conductive interconnections from the illustrated FET 100 to other components (including other FETs) and/or external contacts, passivation layers, and protective coatings.

FIG. 1B is a top plan view of the prior art SOI IC structure of FIG. 1A. The cross-section shown in FIG. 1A is along line X1-X1 of FIG. 1B. The source S, the gate structure G, and the drain D overlay a field of N+ material 140 in this example. The drift region between the gate structure G and the drain D is shown within a dotted outline 141. The illustrated example shows that the source S is associated with multiple source contacts 112 and the drain D is associated with multiple drain contacts 116, while the gate structure G in this particular example is shown as having a single gate contact 114. Also shown in FIG. 1B is the top side of a body contact region 142 having an associated conductive body contact 144. In the illustrated example, the body contact region 142 comprises a P+ region formed in electrical contact with the P− body B to provide a fourth terminal to the FET 100.

FIG. 1C is a stylized cross-sectional view of the SOI IC structure of FIG. 1B taken along line X2-X2. Similar in many aspects to the view shown in FIG. 1A, the view in FIG. 1B includes the body contact region 142 and the associated conductive body contact 144 placed to a first side of the gate structure G. In some embodiments, a conductive substrate contact (not shown) that penetrates through the active layer 106 to a P-type region in contact with the substrate 102 may be placed to a second side of the gate structure G to form a fifth terminal to the FET 100.

FIG. 1D is a schematic diagram of an equivalent circuit for the FET 100 shown in FIGS. 1A-1C. The body B is essentially coupled to the gate terminal G through an equivalent capacitor C_{G}, to the substrate through an equivalent capacitor C_{S}, to the source through an equivalent diode D_{S}, and to the drain through an equivalent diode D_{D}. Notably, the body contact region 142 presents an equivalent body-to-source resistance R_{BTS} coupled to the body B of the FET.

Referring back to FIG. 1B, the two edges of the gate structure G (within the reference ovals 128, perpendicular to the source-side and drift-region-side of the gate structure G) where the gate structure G crosses the boundary between the doped source/drain regions and the field of N+ material 140 can effectively create parasitic “edge transistors” due to depletion of dopant atoms (e.g., B+ boron) into growing oxide during the gate oxidation process. The dopant migration causes the dopant concentration in the semiconductor (e.g., silicon) at the edges 128 of the gate structure G to be lower than in the central region of the FET conduction channel, resulting in a reduction of threshold voltage VTE at the edges 128 compared to the threshold voltage VTC of the central region. The consequence is significant current leakage at the edges 128 which can increase standby power consumption of a FET by an order of magnitude or more and thus increase overall power consumption of any applications using such FETs.

The present invention is directed to overcoming the drawbacks of conventional NEDMOS and LDMOS FETs.

### SUMMARY

The present invention encompasses MOSFET-based IC architectures that mitigate or eliminate the problems of edge transistors, and result in MOSFETs that are reliable, capable of handling relatively high drain voltages, and have low leakage current. The examples of the invention disclosed below represent SOI IC NEDMOS structures, but the invention may also be used for a bulk semiconductor IC LDMOS structure.

One embodiment includes an IC fabricated on a substrate and including end-cap body contact regions angle-implanted to have a first semiconductor characteristic, a drift region doped to have a second semiconductor characteristic, and a gate structure partially overlying the end-cap body contact regions and the drift region, the gate structure including a conductive layer having a third semiconductor characteristic, the conductive layer including a first side angle-implanted to have the first semiconductor characteristic. Steps for fabricating such an IC include implanting a first dopant at an angle from the vertical in the range of about 5° to about 60° within the end-cap body contact regions and within a first side of the conductive layer in a region of the gate structure overlying the end-cap body contact regions, wherein the first dopant results in a first semiconductor characteristic for the end-cap body contact regions and the first side of the conductive layer.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a stylized cross-sectional view of a typical prior art SOI IC structure for a single NEDMOS FET.

FIG. 1B is a top plan view of the prior art SOI IC structure of FIG. 1A.

FIG. 1C is a stylized cross-sectional view of the SOI IC structure of FIG. 1B taken along line X2-X2.

FIG. 1D is a schematic diagram of an equivalent circuit for the FET shown in FIGS. 1A-1C.

FIG. 2A is a stylized top plan view of a single SOI NEDMOS FET in accordance with the present invention.

FIG. 2B is a stylized cross-sectional view of the IC structure of FIG. 2A taken along line X-X.

FIG. 2C is a stylized cross-sectional view of an alternative version of the IC structure of FIG. 2A taken along line X-X.

FIG. 3 is a graph of OFF-state drain leakage current I_{D} and breakdown voltage BV_{DSS} characteristics as a function of drain-to-source voltage V_{DS} for a modeled conventional NEDMOS FET having a centered body contact region and a model of an improved NEDMOS FET having end-cap body contact regions with angled gate structure G dopants in accordance with the present invention.

FIG. 4A is a stylized top plan view of a single NEDMOS FET having a dual-thickness active area.

FIG. 4B is a stylized cross-sectional view of the IC structure of FIG. 4A taken along line Y-Y.

FIG. 4C is a stylized cross-sectional view of the IC structure of FIG. 4A taken along line X1-X1.

FIG. 4D is a stylized cross-sectional view of the IC structure of FIG. 4A taken along line X2-X2.

FIG. 5 is a stylized cross-sectional view of the IC structure of another variant of the inventive architecture.

FIG. 6 is a stylized cross-sectional view of the IC structure of another variant of the inventive architecture.

FIG. 7 is a top plan closeup view of an end-cap body contact region showing a first example layout on a silicon region Si.

FIG. 8 is a top plan closeup view of an end-cap body contact region showing a second example layout on a silicon region Si.

FIG. 9 is a top plan closeup view of an end-cap body contact region showing a third example layout on a silicon region Si.

FIG. 10 is a top plan closeup view of an end-cap body contact region showing a fourth example layout on a silicon region Si.

FIG. 11 is a top plan view of a variant of the structure shown in FIG. 2A.

FIG. 12 is a process flowchart showing one process that is suitable for some contemporary IC front-end-of-line (FEOL) foundries.

FIG. 13 is a top plan view of a substrate that may be, for example, a printed circuit board or chip module substrate (e.g., a thin-film tile).

FIG. 14 is a process flow chart showing a first method for fabricating an integrated circuit in accordance with the present invention.

FIG. 15 is a process flow chart showing a second method for fabricating an integrated circuit in accordance with the present invention.

Like reference numbers and designations in the various drawings indicate like elements unless the context requires otherwise.

### DETAILED DESCRIPTION

The present invention encompasses MOSFET-based IC architectures that mitigate or eliminate the problems of edge transistors, and result in MOSFETs that are reliable, capable of handling relatively high drain voltages, and have low leakage current.

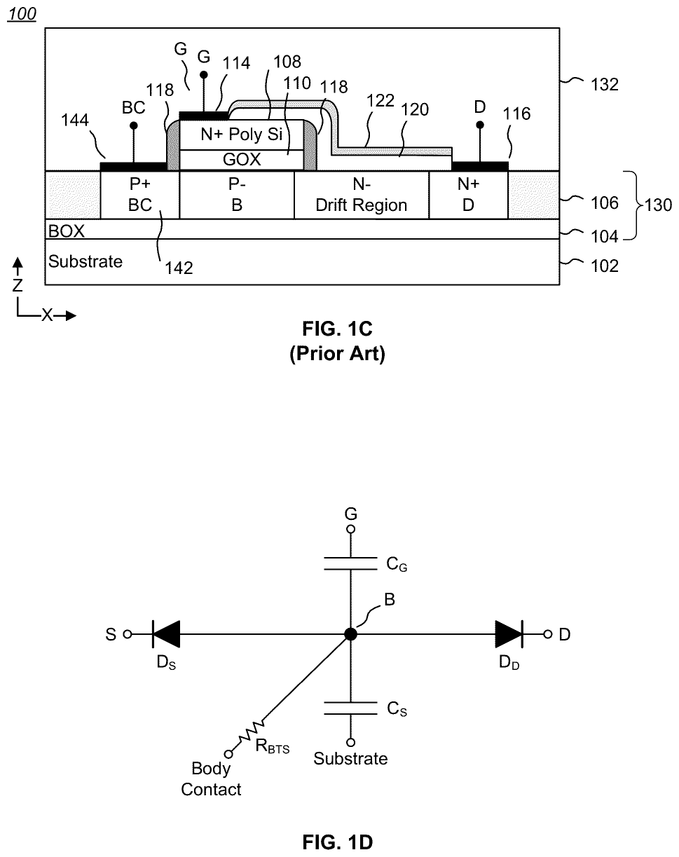

FIG. 2A is a stylized top plan view of a single SOI NEDMOS FET 200 in accordance with the present invention. FIG. 2B is a stylized cross-sectional view of the IC structure of FIG. 2A taken along line X-X. FIG. 2C is a stylized cross-sectional view of an alternative version of the IC structure of FIG. 2A taken along line X-X. Note that in FIGS. 2A-2C, the dimensions for the elements of the IC structure are not to scale; some dimensions have been exaggerated for clarity or emphasis. Note also that a superstructure 132 is omitted to avoid clutter

In the example shown in FIG. 2A, the source S, a modified gate structure G, and the drain D overlay a field of N+ material 140. The drift region between the gate structure G and the drain D is shown within a dotted outline 141. The illustrated example shows that the source S is associated with multiple source contacts 112 and the drain D is associated with multiple drain contacts 116, while the gate structure G in this particular example is shown as having a single gate contact 114 (but is not limited to a single gate contact).

Also shown in FIG. 2A is the top side of two “end-cap” body contact regions 202 each having an associated conductive body contact 204, such as a salicide (e.g., NiSi or a NiSi conducting layer that connects a P+ body contact region to an N+ gate region). In the illustrated example, the body contact region 202 comprises an extended P+ region formed in electrical contact with the P− body B to provide a fourth terminal to the FET 200. The body contact region 202 in a FET fabricated on an SOI substrate is of a special importance—the body contact region 202 eliminates or substantially mitigates the floating body current effect; mitigates turn-on of the parasitic bipolar devices inherent in a MOSFET; improves the breakdown voltage of the FET; improves electro-static discharge (ESD) protection for the FET; improves device and circuitry performance and capability, and in particular improves circuit linearity, reliability, and power consumption in analog and digital circuitry, especially for such devices as RF and mmWave switches, low-noise amplifiers (LNAs), and power amplifiers (PAs).

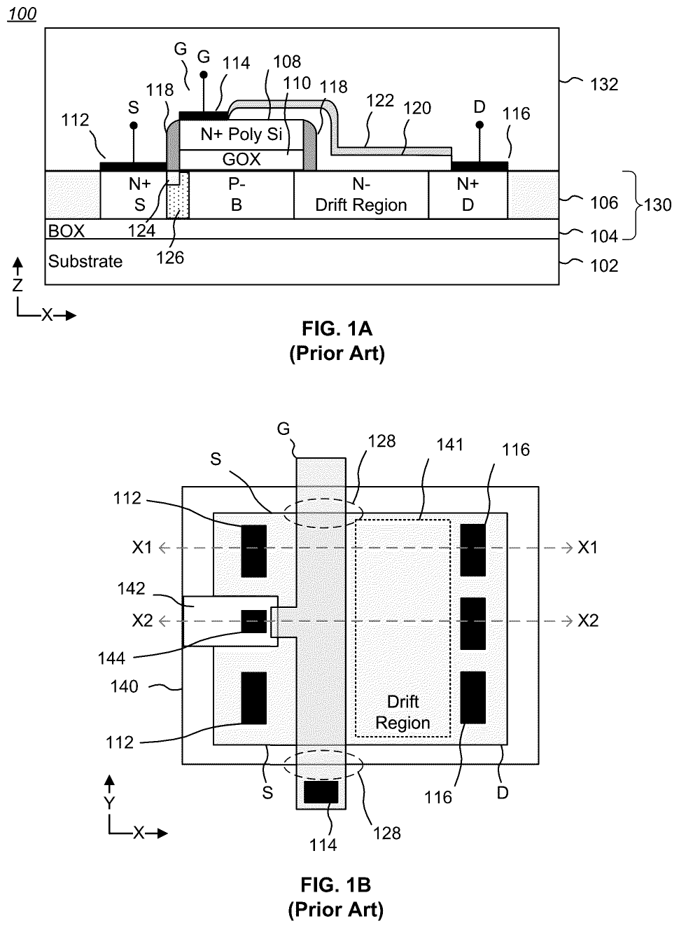

Elements in the cross-sectional view of the FET 200 shown in FIG. 2B that are the same as the embodiment shown in FIG. 1C have the same reference numbers or letters. In FIG. 2B, the body contact region 202 and a region 206 of the N+ conductive layer 108 of the gate structure G have been modified with a P+ type dopant (e.g., boron) implanted at an angle before formation of the associated conductive body contact 204. The angle is sufficient to extend the body contact region 202 further underneath the gate structure G than a conventional architecture, and to convert the region 206 of the N+ conductive layer 108 to have a P+ attribute. The P+ type dopant may be implanted, for example, by ion implantation, and the implantation angle θ₁ from the vertical may be in the range of about 5° to about 60°, and is preferably in the range of about 7° to about 45°. The implantation angle preferably should be sufficient to implant P+ dopant at the edge of the conductive layer 108 nearest the body contact region 202 to a penetration depth of about 0.1 to 0.5 μm.

The effect of the angled implantation into the region 206 is to modify the work function Φ along the X-dimension of the gate structure G with respect to the underlying portions of the active layer 106, which in turn modifies the threshold voltage V_{T} of the corresponding portions of the conduction channel of the parasitic edge transistors associated with the gate structure G. For example, referring to FIG. 2B, four different zones of threshold voltage V_{T} are identified, corresponding to four different work functions Φ created by different Z-dimension “stacks” of materials within the gate structure G, as shown in TABLE 1 below.

TABLE 1
Structural and V_{T} related details of gate edge regions

| | GATE STRUCTURE G REGION | | | |
|---|---|---|---|---|
| V_{T} Zone ID | V_{T}1 | V_{T}2 | V_{T}3 | V_{T}4 |
| Gate Structure Region Vertical | gate contact/ | gate contact/ | N+ poly Si | N+ poly Si/ |
| Stack Composition | P+ poly Si | N+ poly Si | | N− drift region |
| Active Layer 106 region | P+ BC | Channel | | N− drift region |
| Relative V_{T} Value | V_{T}++ | V_{T}+ | V_{T} | V_{T}−− |
| Conductivity @ V_{G} = 0 V | OFF | OFF | ON | ON |

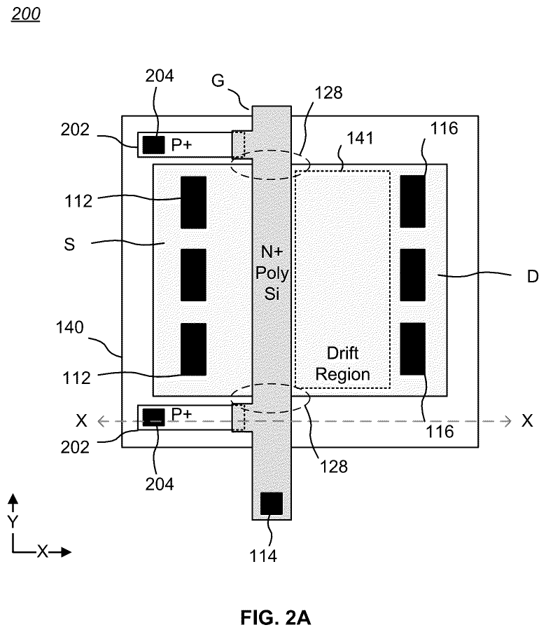

Note that the V_{T} zones are not sharply delimited, as suggested by the dashed lines, but instead the zones blend somewhat into adjacent zones in a continuous manner. However, even in blended form, by using the V_{T} zones together, a lower leakage current value is achieved. Note also that the converted P+ characteristic of the region 206 of the N+ conductive layer 108 provides a much higher V_{T} value in zone V_{T}1 than in the channel (zone V_{T}3), significantly improving the drain-to-source breakdown voltage BV_{DSS} of the device (see also FIG. 3 below). Further, the high V_{T} P+ region 206 of the gate structure G mitigates or eliminates what would otherwise be a low threshold voltage V_{TE} at the edges 128 of the gate structure G compared to the threshold voltage V_{TC} of the central region of the FET device.

FIG. 2C depicts a variant embodiment of the FET device shown in FIG. 2C, with an extra implant into the gate structure G. Elements in FIG. 2C that are the same as the embodiment shown in FIG. 2B have the same reference numbers or letters. In FIG. 2C, a region 216 of the N+ conductive layer 108 of the gate structure G have been modified with a P-type dopant (e.g., boron) implanted at an angle, but at a concentration of dopant less than the P+ region 206. The angle is sufficient to convert the region 216 of the N+ conductive layer 108 to have an N attribute. The P-type dopant may be implanted, for example, by ion implantation, and the implantation angle θ₂ from the vertical may be in the range of about 5° to about 60°, and is preferably in the range of about 7° to about 45°. The implantation angle preferably should be sufficient to implant P-type dopant at the edge of the conductive layer 108 nearest the N− drift region to a penetration depth of about 0.005 to 0.26 μm.

The effect of the angled implantation into the region 216 is to further modify the work function Φ along the X-dimension of the gate structure G with respect to the underlying portions of the active layer 106, which in turn modifies the threshold voltage V_{T} of the corresponding portions of the conduction channel of the parasitic edge transistors associated with the gate structure G. For example, referring to FIG. 2C, five different zones of threshold voltage V_{T} are identified, corresponding to five different work functions Φ created by different Z-dimension “stacks” of materials within the gate structure G, as shown in TABLE 2 below.

TABLE 2
Structural and V_{T} related details of gate edge regions

| | GATE STRUCTURE G REGION | | | | |
|---|---|---|---|---|---|
| V_{T} Zone ID | V_{T}1 | V_{T}2 | V_{T}3 | V_{T}4 | V_{T}5 |
| Gate Structure | gate contact/ | gate contact/ | N+ poly Si | N poly Si | N poly Si/ |
| Region Vertical | P+ poly Si | N+ poly Si | | | N− drift region |
| Stack | | | | | |
| Composition | | | | | |
| Active Layer | P+ BC | Channel | | | N− drift region |
| 106 region | | | | | |
| Relative V_{T} | V_{T}++ | V_{T}+ | V_{T} | V_{T}− | V_{T}−− |
| Value | | | | | |
| Conductivity @ | OFF | OFF | OFF | ON | ON |
| V_{G} = 0 V | | | | | |

Again, the V_{T} zones are not sharply delimited, as suggested by the dashed lines, but instead the zones blend somewhat into adjacent zones in a continuous manner. Compared to of the embodiment of FIG. 2B, while retaining the high breakdown voltage BV_{DSS} characteristic and the mitigation or elimination of the otherwise low threshold voltage V_{TE} at the edges 128 of the gate structure G, the converted N characteristic of the region 216 of the N+ conductive layer 108 further provides a smoother transition of threshold voltages between the V_{T}3 zone and the V_{T}5 zone.

FIG. 3 is a graph 300 of OFF-state drain leakage current I_{D} and breakdown voltage BV_{DSS} characteristics as a function of drain-to-source voltage V_{DS} for a modeled conventional NEDMOS FET having a centered body contact region 142 and a model of an improved NEDMOS FET having end-cap body contact regions 202 with angled gate structure G dopants in accordance with the present invention. Graph line 302 corresponds to the conventional NEDMOS FET, while graph line 304 corresponds to the improved NEDMOS FET. As the graph 300 indicates, the BV_{DSS} value at marker line 306 for the conventional NEDMOS FET is over 3V less than the BV_{DSS} value at marker line 308 for the improved NEDMOS FET, while the leakage current for the conventional NEDMOS FET ranges from about 2.5 to 3 orders of magnitude more than the leakage current for the improved NEDMOS FET.

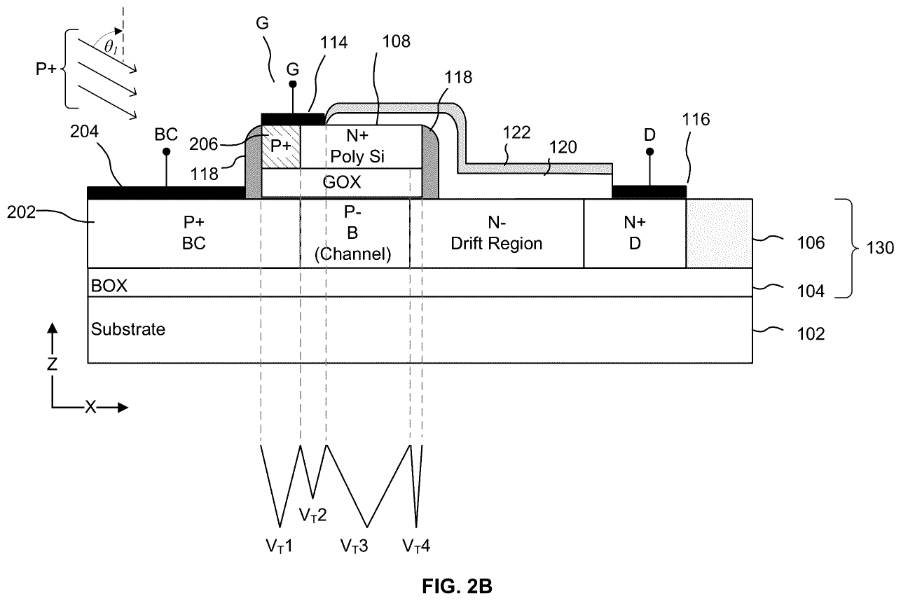

A number of variations of the structures shown in FIG. 2A-2C are contemplated as being within the scope of the invention. For example, FIG. 4A is a stylized top plan view of a single NEDMOS FET 400 having a dual-thickness active area. FIG. 4B is a stylized cross-sectional view of the IC structure of FIG. 4A taken along line Y-Y. In this embodiment, a central portion 402 of the active area 106 is thinner relative to the edge regions 404 in which the end-cap body contact regions 202 are formed. The difference in relative thickness of the central portion 402 compared to the edge regions 404 may be accomplished by thinning down the central portion 402 (e.g., by etching or the like) or by building up the edge regions 404 (e.g., by epitaxial layers).

FIG. 4C is a stylized cross-sectional view of the IC structure of FIG. 4A taken along line X1-X1. The FET structure in the central portion 402 looks essentially the same as the conventional FET 100 of FIG. 1A fabricated in a thin active layer 106. FIG. 4D is a stylized cross-sectional view of the IC structure of FIG. 4A taken along line X2-X2. The end-cap body contact of the FET structure in the edge portion 404 looks essentially the same as in the improved angle-implanted FET of FIG. 2C, fabricated in a thicker active layer 106′.

A thinner central portion 402 of the active area 106 generally results in a lower V_{TC} for the FET, while the thicker edge regions 404 generally results in a higher V_{TE} for the parasitic edge transistors. Adjusting the relative thickness of the central portion 402 versus the edge regions 404 allows V_{TE} to be set at or above V_{TC}, thus mitigating or eliminating the effects (particularly current leakage) of the edge transistors.

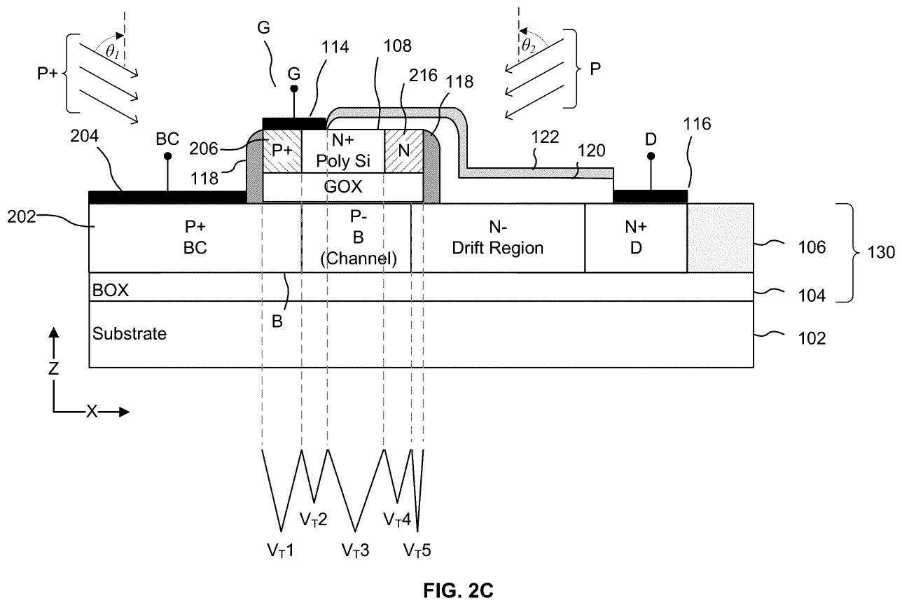

FIG. 5 is a stylized cross-sectional view of the IC structure 500 of another variant of the inventive architecture. In the illustrated example, the GOX layer 502 is modified to have two levels, either by thinning a first region of a deposited GOX material (leaving an adjacent thicker region) or building up a thicker second region adjacent a thinner first region (e.g., by depositing or forming additional GOX material on a portion of an initial thinner layer of GOX material). The 2-level GOX layer 502 would extend to the end-cap body contact regions 202 and thus provide another way to control the V_{TE} of the parasitic edge transistors. The 2-level GOX layer 502 would also enable the FET to withstand higher gate voltages VG. In some embodiments, the GOX layer 502 may have more than two levels—a thicker gate oxide at the edge region would have a higher V_{TE} and thus also reduces edge current leakage.

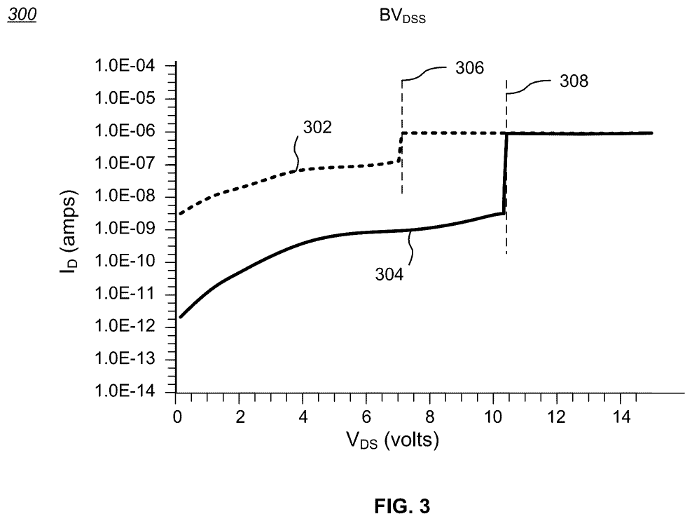

FIG. 6 is a stylized cross-sectional view of the IC structure 600 of another variant of the inventive architecture. In the illustrated example, a P− implant region 602 has been formed, such as by ion implantation, within the N− drift region and beneath the drain-side spacer 118. The P− implant region 602 enables the FET to withstand higher gate voltages VG. The P− implant region 602 also has a higher edge FET V_{TE} and thus also reduces edge current leakage.

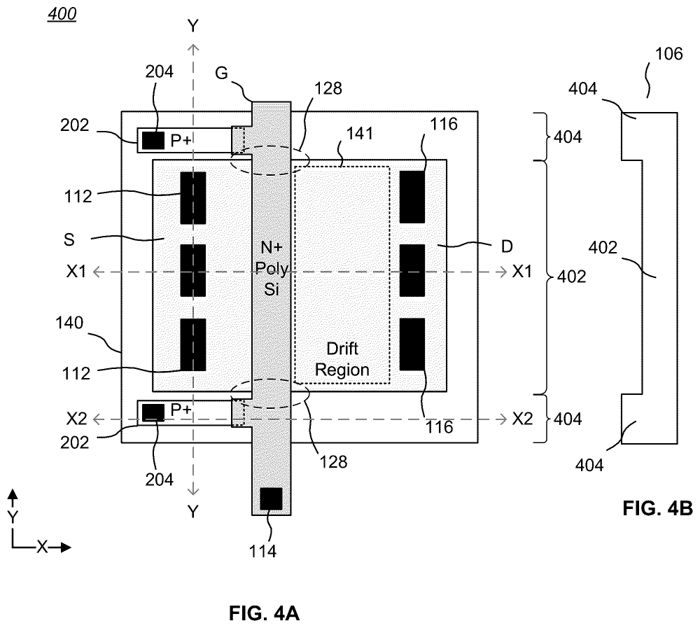

FIG. 7 is a top plan closeup view of an end-cap body contact region 202 showing a first example layout 700 on a silicon region Si. In the illustrated example, a portion of a polysilicon layer of a gate structure G overlies the body contact region 202 and an N+ region is adjacent the contact region 202. The body contact region 202 has a length w1 in the X-dimension, and projects only part way underneath the polysilicon layer.

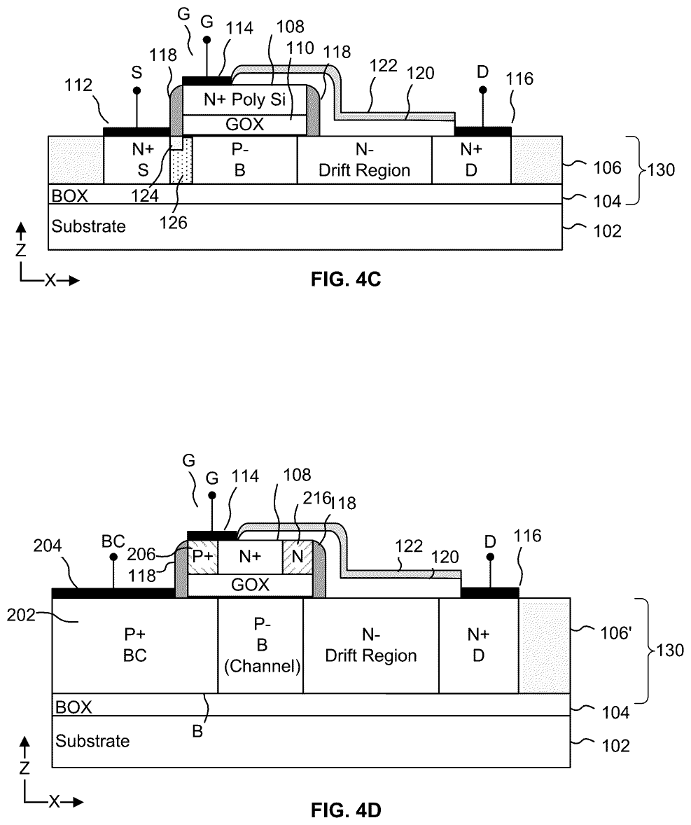

FIG. 8 is a top plan closeup view of an end-cap body contact region 202 showing a second example layout 800 on a silicon region Si. In the illustrated example, the body contact region 202 has a length w2 (greater than w1) in the X-dimension, and projects further underneath the polysilicon layer than the example shown in FIG. 7. Accordingly, more of the edge of the gate structure G is covered by the end-cap body contact region 202. Another advantage is that the geometry shown in FIG. 8 provides for more greater manufacturing tolerances in defining implant regions.

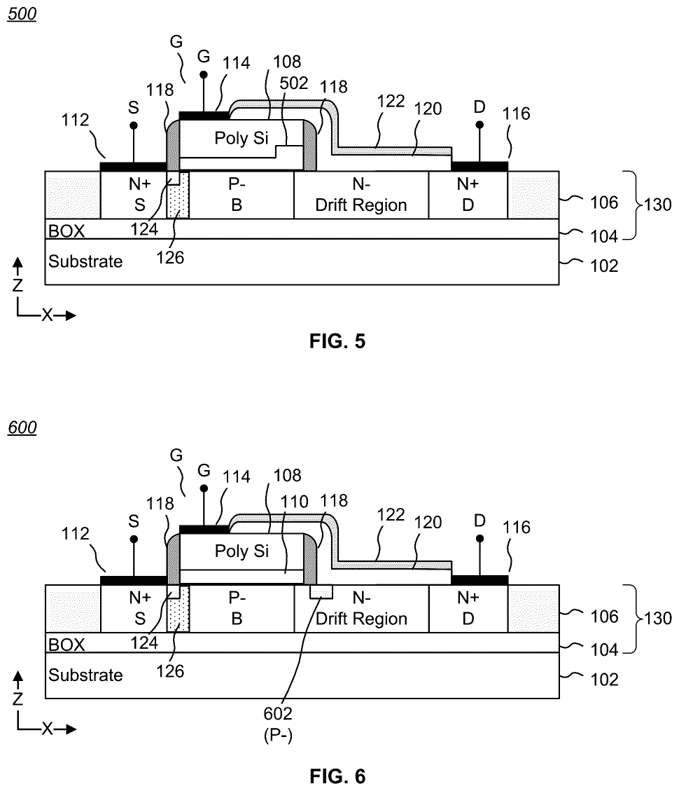

FIG. 9 is a top plan closeup view of an end-cap body contact region 202 showing a third example layout 900 on a silicon region Si. In the illustrated example, the polysilicon layer of the gate structure G has been shaped to increase its length in the X-dimension, which helps increase the V_{TE} of the parasitic edge transistor. In addition, a stepped section (within dashed oval 902) reduces the parasitic capacitance between the polysilicon layer and the body contact region 202 compared to the layouts shown in FIGS. 7 and 8. The dimensions and number of steps of the stepped section are a matter of design choice.

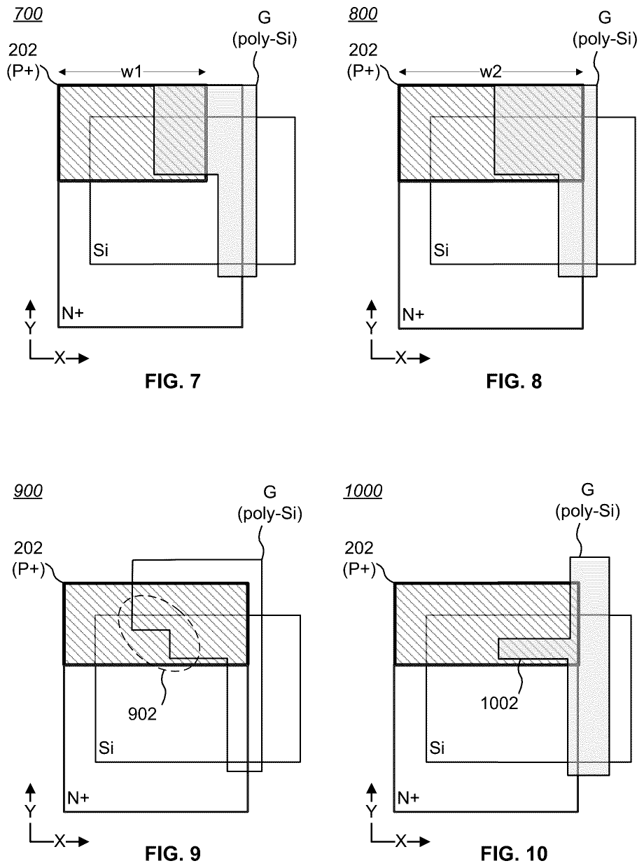

FIG. 10 is a top plan closeup view of an end-cap body contact region 202 showing a fourth example layout 1000 on a silicon region Si. In the illustrated example, the polysilicon layer of the gate structure G has been shaped to have a narrow projection 1002 overlying the body contact region 202, which lowers the body-to-source resistance R_{BTS}.

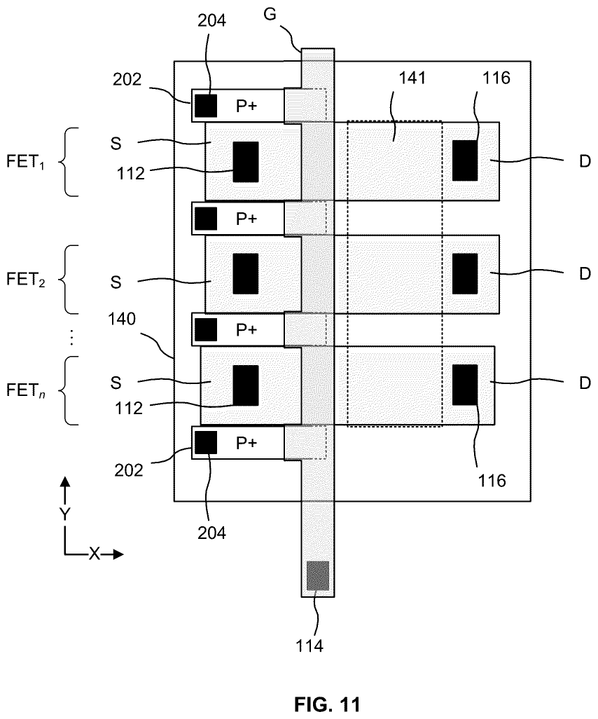

FIG. 11 is a top plan view of a variant of the structure shown in FIG. 2A. In the illustrated example, multiple devices (FET₁-FETₙ) are formed on an IC substrate and separated by shared end-cap body contact regions 202, which reduce edge current leakage. The illustrated architecture, a form of segmented transistor, allows higher current levels. In a variant embodiment, each device is provided with its own gate, thus allowing dynamic selection of the number of conductive channels that are concurrently ON or OFF.

Note that while the examples of the invention disclosed above represent SOI IC NEDMOS structures, the invention may be used for a bulk semiconductor IC LDMOS structure. It also should be appreciated that a number of features described above may be “mixed and matched” to create further variations without departing from the scope of the invention. For example, a FET having a 2-level GOX layer 502 may also include a P− implant region 602, utilize any of the end-cap geometries shown in FIGS. 7-10, and be laid out with other FET devices in the manner shown in FIG. 11. Still other combinations of features may be selected for particular applications.

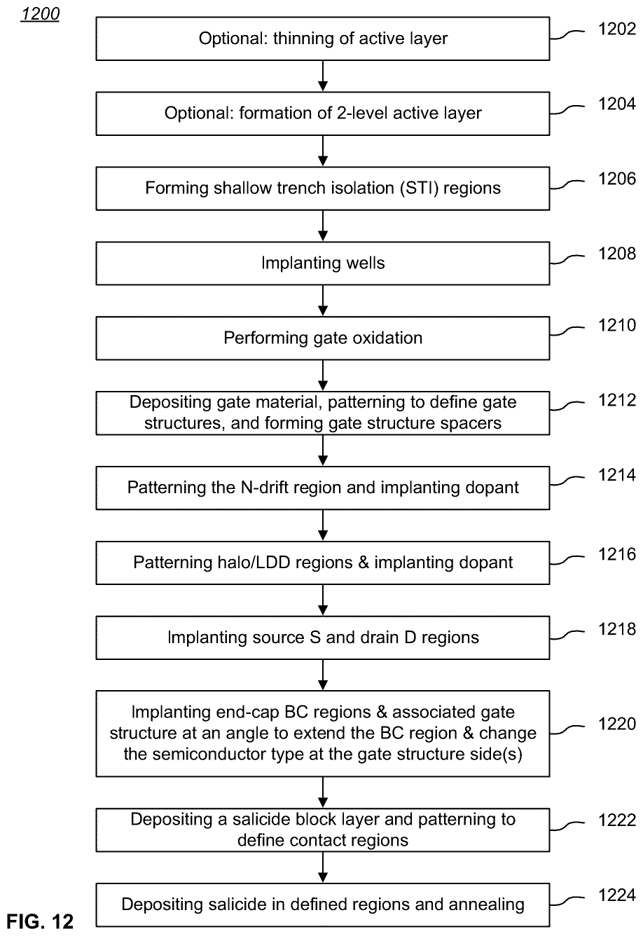

A number of different processes may be used to fabricate the IC architectures disclosed above. FIG. 12 is a process flowchart showing one process that is suitable for some contemporary IC front-end-of-line (FEOL) foundries. Note that some conventional steps, such as planarization, passivation, affirmative statements regarding masking and etching, and superstructure formation have been omitted as known to those of ordinary skill in the art. The illustrated process includes:

If needed, thinning the semiconductor active layer (e.g., Si, Ge, SiGe) to a suitable thickness (Step 1202). For example, commercially available SOI wafers may have an active layer thickness of about 750 Å. It may be useful for some applications, particularly for RF ICs, to thin the active layer, such as to about 500 Å.

If a 2-level active area is desired (e.g., a thin FET channel and a thick body edge region), then patterning a semiconductor active layer having a thick profile and etching to create a thin central region, or patterning a semiconductor active layer having a thin profile and forming thick edge regions (e.g., by epitaxial growth of additional semiconductor material) (Step 1204).

Forming shallow trench isolation (STI) regions (Step 1206).

Implanting wells (e.g., P-type for NEDMOS devices) (Step 1208).

Performing gate oxidation (Step 1210).

Depositing gate material (e.g., poly-Si), patterning (e.g., masking and etching) to define gate structures, and forming gate structure spacers (Step 1212).

Patterning the N− drift region and implanting dopant (Step 1214).

Optionally, patterning halo and/or LDD regions and implanting dopant (Step 1216).

Implanting source S and drain D regions (Step 1218).

Implanting end-cap body contact regions and the associated gate structures at an angle to extend the body contact region to beneath the gate structure and to change the semiconductor type at one side or both sides of the gate structures adjacent to the spacers, thus enabling lower body resistance at the edges; see, for example, FIGS. 2B and 2C and associated description (Step 1220).

Depositing a salicide block layer and patterning to define contact regions (Step 1222).

Depositing salicide (e.g., NiSi) in defined contact regions and annealing (Step 1224).

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

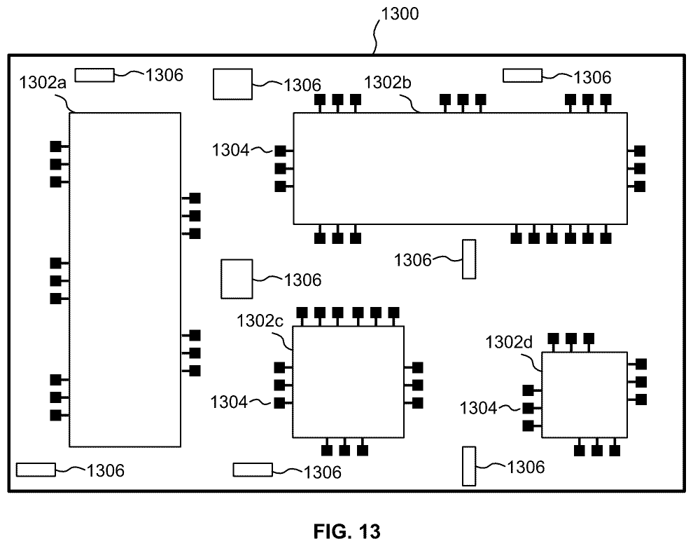

As one example of further integration of embodiments of the present invention with other components, FIG. 13 is a top plan view of a substrate 1300 that may be, for example, a printed circuit board or chip module substrate (e.g., a thin-film tile). In the illustrated example, the substrate 1300 includes multiple ICs 1302a-1302d having terminal pads 1304 which would be interconnected by conductive vias and/or traces on and/or within the substrate 1300 or on the opposite (back) surface of the substrate 1300 (to avoid clutter, the surface conductive traces are not shown and not all terminal pads are labelled). The ICs 1302a-1302d may embody, for example, signal switches, active and/or passive filters, amplifiers (including one or more LNAs), and other circuitry. For example, IC 1302b may incorporate one or more instances of an NEDMOS or LDMOS transistor fabricated in accordance with the teachings of this disclosure.

The substrate 1300 may also include one or more passive devices 1306 embedded in, formed on, and/or affixed to the substrate 1300. While shown as generic rectangles, the passive devices 1306 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 1300 to other passive devices 1306 and/or the individual ICs 1302a-1302d. The front or back surface of the substrate 1300 may be used as a location for the formation of other structures.

Embodiments of the present invention are useful in a wide variety of larger radio frequency (RF) circuits and systems for performing a range of functions, including (but not limited to) RF power amplifiers, RF low-noise amplifiers (LNAs), antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

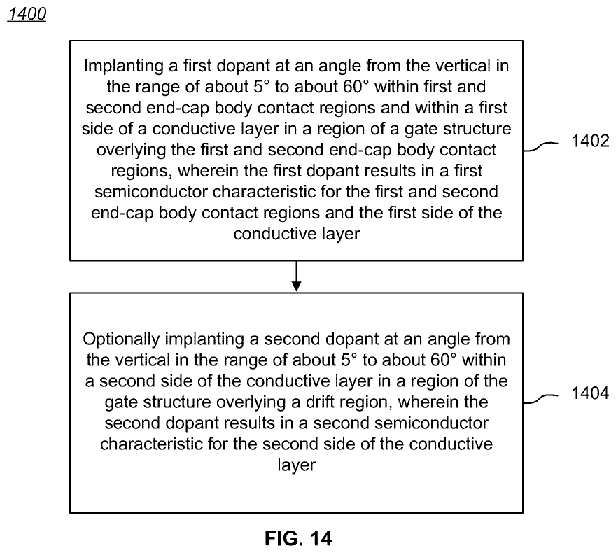

Another aspect of the invention includes methods for fabricating an IC with angled implants to at least one side of a gate structure and to end-cap body contact regions. For example, FIG. 14 is a process flow chart 1400 showing a first method for fabricating an integrated circuit in accordance with the present invention. The method includes: implanting a first dopant at an angle from the vertical in the range of about 5° to about 60° within first and second end-cap body contact regions and within a first side of a conductive layer in a region of a gate structure overlying the first and second end-cap body contact regions, wherein the first dopant results in a first semiconductor characteristic for the first and second end-cap body contact regions and the first side of the conductive layer (Block 1402). Optionally, the method further includes implanting a second dopant at an angle from the vertical in the range of about 5° to about 60° within a second side of the conductive layer in a region of the gate structure overlying a drift region, wherein the second dopant results in a second semiconductor characteristic for the second side of the conductive layer (Block 1404).

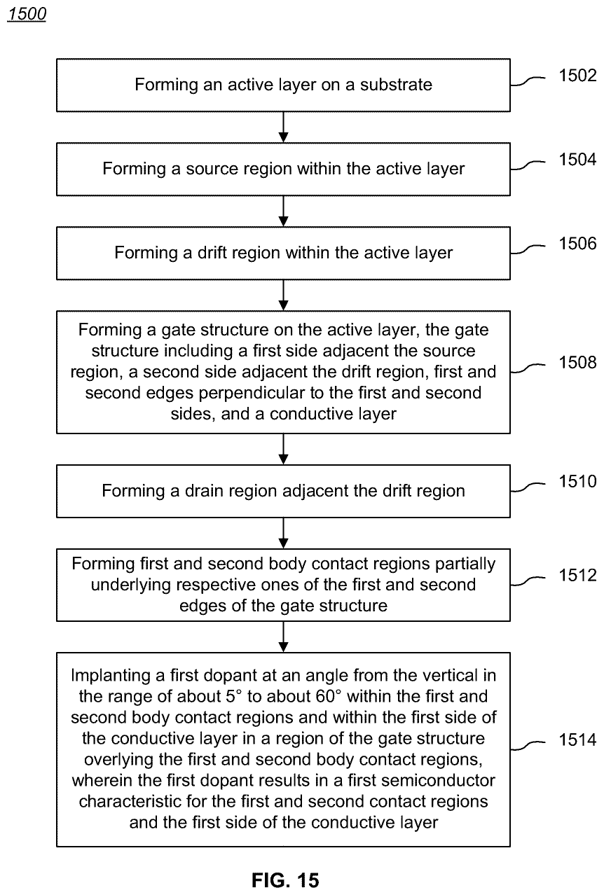

As another example FIG. 15 is a process flow chart 1500 showing a second method for fabricating an integrated circuit in accordance with the present invention. The method includes: forming an active layer on a substrate (Block 1502); forming a source region within the active layer (Block 1504); forming a drift region within the active layer (Block 1506); forming a gate structure on the active layer, the gate structure including a first side adjacent the source region, a second side adjacent the drift region, first and second edges perpendicular to the first and second sides, and a conductive layer (Block 1508); forming a drain region adjacent the drift region (Block 1510); forming first and second body contact regions partially underlying respective ones of the first and second edges of the gate structure (Block 1512); and implanting a first dopant at an angle from the vertical in the range of about 5° to about 60° within the first and second body contact regions and within the first side of the conductive layer in a region of the gate structure overlying the first and second body contact regions, wherein the first dopant results in a first semiconductor characteristic for the first and second contact regions and the first side of the conductive layer (Block 1514). Optionally, the method further includes implanting a second dopant at an angle from the vertical in the range of about 5° to about 60° within a second side of the conductive layer in a region of the gate structure overlying a drift region, wherein the second dopant results in a second semiconductor characteristic for the second side of the conductive layer (see block 1404 of FIG. 14).

Additional aspects of the above methods may include one or more of the following: wherein the first semiconductor characteristic is a P+ type; wherein the second semiconductor characteristic is an N type; wherein the conductive layer is N+ polysilicon; and/or wherein the conductive layer is N+ polysilicon and the first semiconductor characteristic is a P+ type.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as BiCMOS, LDMOS, BCD, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. An integrated circuit fabricated on a substrate and including:
(a) end-cap body contact regions doped to have a first semiconductor characteristic;
(b) a drift region doped to have a second semiconductor characteristic; and
(c) a gate structure partially overlying the end-cap body contact regions and the drift region, the gate structure including a conductive layer having a third semiconductor characteristic, the conductive layer including a first side doped to have the first semiconductor characteristic.

2. The integrated circuit of claim 1, wherein the second semiconductor characteristic is an N− type.

3. The integrated circuit of claim 1, wherein the conductive layer is polysilicon, the third semiconductor characteristic is an N+ type, and the first semiconductor characteristic is a P+ type.

4. The integrated circuit of claim 1, wherein the conductive layer further includes a second side near the drift region, wherein the second side is doped to have a fourth semiconductor characteristic.

5. The integrated circuit of claim 4, wherein the conductive layer is polysilicon, the third semiconductor characteristic is an N+ type, the first semiconductor characteristic is a P+ type, and the fourth semiconductor characteristic is an N type.

6. The integrated circuit of claim 1, wherein the integrated circuit further includes a field-effect transistor region between the end-cap body contact regions.

7. The integrated circuit of claim 6, wherein the integrated circuit includes an active layer having a thin region and a thick region, wherein the field-effect transistor region is fabricated in and on the thin region and the end-cap body contact regions are fabricated on the thick region.

8. The integrated circuit of claim 1, wherein the conductive layer of the gate structure is fabricated to have at least two levels in series between the first side of the conductive layer and an opposing second side of the conductive layer.

9. The integrated circuit of claim 1, wherein a portion of the drift region near the gate structure is doped to have a fifth semiconductor characteristic.

10. The integrated circuit of claim 9, wherein the fifth semiconductor characteristic is a P-type.

11. (canceled)

12. An integrated circuit fabricated on a substrate and including:
(a) a source region;
(b) a drift region;
(c) a gate structure including a first side adjacent the source region, a second side adjacent the drift region, and first and second edges perpendicular to the first and second sides;
(d) a drain region adjacent the drift region;
(e) first and second body contact regions partially underlying respective ones of the first and second edges of the gate structure and doped to have a first semiconductor characteristic;
wherein the first and second edges of the gate structure partially overly respective ones of the first and second body contact regions and the drift region, the gate structure including a conductive layer having a second semiconductor characteristic, the conductive layer including a first side doped near the first and second body contact regions to have the first semiconductor characteristic.

13. The integrated circuit of claim 12, wherein the drift region has an N− type characteristic.

14. The integrated circuit of claim 12, wherein the conductive layer is polysilicon, the second semiconductor characteristic is an N+ type, and the first semiconductor characteristic is a P+ type.

15. The integrated circuit of claim 12, wherein the conductive layer further includes a second side near the drift region, wherein the second side is doped to have a third semiconductor characteristic.

16. The integrated circuit of claim 15, wherein the conductive layer is polysilicon, the second semiconductor characteristic is an N+ type, the first semiconductor characteristic is a P+ type, and the third semiconductor characteristic is an N type.

17. The integrated circuit of claim 12, wherein the integrated circuit further includes a field-effect transistor region between the first and second end-cap body contact regions.

18. The integrated circuit of claim 17, wherein the integrated circuit includes an active layer having a thin region and a thick region, wherein the field-effect transistor region is fabricated in and on the thin region and the first and second end-cap body contact regions are fabricated on respective portions of the thick region.

19. The integrated circuit of claim 12, wherein the conductive layer of the gate structure is fabricated to have at least two levels in series between the first side and the second side of the conductive layer.

20. The integrated circuit of claim 12, wherein a portion of the drift region near the gate structure is doped to have a fourth semiconductor characteristic.

21. The integrated circuit of claim 20, wherein the fourth semiconductor characteristic is a P-type.

22.-24. (canceled)
